(19) United States
(12) Patent Application Publication
(10) Pub. No.: US 2026/0047218 A1
(43) Pub. Date: Feb. 12, 2026

(54) PHOTODETECTOR COMPRISING AMORPHOUS SELENIUM AND OPTIONALLY TELLURIUM

(71) Applicant: The Regents of the University of California, Oakland, CA (US)

(72) Inventors: Shiva Abbaszadeh, Santa Cruz, CA (US); Kaitlin Hellier, Santa Cruz, CA (US)

(73) Assignee: The Regents of the University of California, Oakland, CA (US)

(21) Appl. No.: 19/150,083

(22) PCT Filed: Feb. 6, 2024
(86) PCT No.: PCT/US2024/014580

§ 371 Date: Jul. 22, 2025

Related U.S. Application Data
(60) Provisional application No. 63/483,374, filed on Feb. 6, 2023.

(51) Int. Cl. H10F 39/18; G01T 1/20

(52) U.S. Cl. CPC H10F 39/1898; G01T 1/20181; G01T 1/20184

(57) ABSTRACT

A photodetector comprising an amorphous alloy of selenium and tellurium. Also disclosed is a dual layer detector including the photodetector.

### CROSS REFERENCE TO RELATED APPLICATIONS

This application claims the benefit under 35 U.S.C. Section 119(e) of U.S. Provisional Application No. 63/483,374, filed Feb. 6, 2023, by Shiva Abbaszadeh and Kaitlin Hellier, entitled “PHOTODETECTOR COMPRISING AMORPHOUS SELENIUM AND TELLURIUM,” attorney's docket 284.0019USP1, which application is incorporated by reference herein.

### STATEMENT REGARDING FEDERALLY SPONSORED RESEARCH AND DEVELOPMENT

This invention was made with government support under DE-SC0022343 awarded by the Department of Energy and 1R01EB033466 awarded by the National Institutes of Health. The Government has certain rights in the invention.

### BACKGROUND OF THE INVENTION

### 1. Field of the Invention

The present invention relates to a detector and method of making the same.

### 2. Description of Related Art

Amorphous selenium (a-Se), with a bandgap of approximately ˜2 eV, is one of the best photoconductors used in the photocopy industry. Its fabrication is a mature technology and its photogeneration efficiency was extensively studied during the 1960s and 1970s [1]. It is capable of avalanche multiplication at relatively low fields compared to other common avalanche materials, such as amorphous silicon [2]. Much work has been completed on a-Se as a direct-conversion photoconductive layer on thin-film-transistor (TFT) flat panel imagers and complementary metal-oxide semiconductor (CMOS) readouts for a wide range of X-ray imaging applications, including mammography [3-5]. In addition to X-ray imaging, a-Se is utilized in life sciences, high energy physics, and nuclear radiation detection due to its high absorption and quantum efficiency (QE) in ultraviolet-blue wavelengths (˜0% at 400 nm and 30 V/μm) [6-9]. In most of these applications, a-Se is fabricated as a stabilized alloy (containing 0.3% Arsenic: As and 10 ppm Chlorine: Cl). Adding As is beneficial for preventing crystallization, however it generates deep hole traps. Chlorine, in ppm amounts, is added to compensate for these As induced deep traps, though it increases the density of shallow trap states and slightly reduces hole mobility [10.11].

Despite the improvements seen in optical absorbance, studies have shown that the alloying of Te in a-Se results in a sharp reduction of carrier mobility due to the formation of defect states. Takahashi first found that the decrease in hole mobility saturates around ˜7%, transitioning from local to extended states and increasing

electron trapping [26]. He theorized that lone-pair electrons strongly interacted between Se and Te, with the fluctuation of these energy states giving rise to hole traps within the gap. Kasap and Juhasz later confirmed the reduction in mobility and provided additional evidence that Te induces both shallow and deep traps. The addition of Cl mitigates these deep traps—much as it does in stabilized Se—however Cl inclusion results in a further increase of shallow traps and thus a reduction in mobility [15, 16]. Polischuk et al. verified the formation of deep traps and the

reduction in lifetime for a-Se _{0.926}Te_{0.074}[27]. Reddy and Bhatnagar proposed that the formation of these defect states played a significant role in the reduction of the band gap with increasing Te content, offering several theories on the topic [18]. Such large reductions in mobility and increases in defect states can be expected to have detrimental effects on the quantum efficiency (QE) of Se—Te photoconductors.

Although a great deal of experimental data has been made available in alloying Se and Te for different applications, its charge transport has only been reported at low electric field (≤10 V/μum). However, the mobility under the these operating conditions is not practically useful for detector applications. What is needed, then, are new insights for implementing Se and Te in detector applications. The present disclosure satisfies this need.

### SUMMARY OF THE INVENTION

Illustrative embodiments of the present invention include, but are not limited to, the following.
1. A detector for electromagnetic radiation, comprising:
an active region comprising an amorphous alloy comprising selenium (Se) and tellurium (Te); and
a biasing circuit comprising a first electrical contact and a second electrical contact to the active region, the biasing circuit for applying an electric field of at least 20 Volts per micrometer (V/μm) between the first contact and the second contact and across the active region.
2. The detector of embodiment 1, wherein the active region comprises less than 12% tellurium.
3. The detector of embodiment 1 or 2, wherein the active region consists essentially of amorphous Se₁₋ₓTeₓ with 0.03≤x≤0.12.
4. The detector of any of the embodiments 1-3, wherein a thickness of the active region between the first contact and the second contact is less than 50 micrometers (μm).
5. The detector of any of the embodiments 1-4, wherein the electric field is in a range of 20 volts per micrometer—30 Volts per micrometer and/or in a range wherein quantum efficiency of the detector for detecting electromagnetic radiation having a wavelength corresponding to ultraviolet wavelengths or blue wavelengths is in a range of 80%-100%.
6. The detector of any of the embodiments 1-5, further comprising a readout circuit comprising the first electrical contact or the second electrical contact, for measuring a photocurrent generated in response to electromagnetic radiation irradiating the active region in a presence of the electric field.
7. An X-ray detection system, comprising:
a first direct detector comprising a first amorphous layer comprising selenium that outputs first charge (e.g., electrons) in response to first X-rays absorbed in the first amorphous layer and having a first energy, wherein the first charge is used to measure the first incident X-rays; and
a second indirect detector under the first direct detector, the second indirect detector comprising a scintillator and a second amorphous layer comprising selenium, wherein:
the scintillator outputs light in response to second X-rays transmitted through the first direct detector and absorbed in the second amorphous layer having a second energy higher than the first energy,
the second amorphous layer outputs second charge (e.g., electrons) in response to the light outputted from the scintillator, and
the second charge is used to measure the second incident X-rays; and
one or more circuits electrically coupled to the first direct detector and second indirect detector so as to receive the first charge and the second charge for measuring the X-rays.
8. The detection system of embodiment 7, wherein at least one of the first amorphous layer or the second amorphous layer comprise an alloy of selenium and tellurium.
9. The system of embodiment 8, wherein the alloy consists essentially of at least 60% selenium and tellurium as the remainder (e.g., tellurium in a range of 1-40%, can be optionally graded).
10. The system of embodiment 7, wherein the first energy is such that at least 50% of the photons of the first absorbed X-rays each have an energy below 50 keV (e.g., 5-50 keV) and the second energy is such that at least 50% of the photons of the second absorbed X-rays have an energy above 50 keV.
11. The system of any of the embodiments 7-10, wherein:
the first direct detector comprises:
   a first electrical contact;
   a second electrical contact;
   a first charge blocking layer between the first amorphous layer and the first electrical contact;
   a second charge blocking layer between the first amorphous layer and the second electrical contact; and
the second indirect detector comprises:
   the scintillator;
   a third electrical contact under the scintillator;
   a third charge blocking layer between the second amorphous layer and the third electrical contact; and
   a fourth charge blocking layer between the second amorphous layer and a fourth electrical contact under the fourth blocking layer.
12. The system of embodiment 11, wherein each of the blocking layers comprise:
an electron blocking layer or a hole blocking layer; and
at least one of parylene, polyimide, hafnium oxide, aluminum oxide, antimony disulphide (for the electron blocking layer).
13. The system of embodiment 11 or 12, further comprising:
a first readout circuit comprising at least one of the first electrical contact or the second electrical contact, for reading out the first charge, and
a second readout circuit comprising at least one of the third electrical contact or the fourth electrical contact, for reading out the second charge.
14. The detection system of embodiment 13, wherein at least one of the readout circuits is configured as a pixel array or imager for forming one or more images using at least the first charge or the second charge.
15. The detection system of embodiment 14, wherein the at least one readout circuit comprises transistors arranged in the pixel array to form a thin film transistor flat panel that generates signals from the first charge and/or the second charge so that the signals can be processed to form the one or more images.
16. The detection system of any of the embodiments 14 or 15, wherein the first energy and the second energy are such that the second charge and the first charge can be used to differentiate, in the one or more images, different materials or densities in a sample that interacted with the X-rays prior to detection using the detection system.
17. The detection system of embodiment 16, wherein the different materials are soft and hard tissue or different amounts of calcification.
18. A particle physics detection system or industrial quality control system comprising the detection system of any of the embodiments 7-16.
19. A medical imager for imaging human tissue comprising the detection system of any of the embodiments 7-17.
20. The detection system of any of the embodiments 7-19, wherein the first direct detector is stacked on top of the second indirect detector and each of the first direct detector and the second indirect detector are formed on a base that maintains the first amorphous layer and the second amorphous layer, respectively, in an amorphous state.
21. The detection system of any of the embodiments 11-20, wherein:
the first electrical contact and the second electrical contact apply a first bias forming a first electric field across the first amorphous layer, and
the third electrical contact and the fourth electrical contact apply a second bias forming a second electric field across the second amorphous layer, and
22. the first electric field is at least 10 V/micron (e.g., 10 V/μm≤E≤50 V/μm),
and
the second electric field is at least 20 V/micron (e.g., 20 V/μm≤E≤50 V/μm).
23. The detection system of embodiment 21, wherein the second amorphous layer comprises tellurium.

The detection of any of the embodiments 1-22, wherein the selenium of the first amorphous layer and/or the second amorphous layer is stabilized selenium comprising 5-20 ppm chlorine and optionally comprises 0.2%-0.5% arsenic.
24. The detector or detection system of any of the embodiments 1-23, wherein one or more of the amorphous layers comprise germanium (e.g., comprise an alloy of selenium and at least one of tellurium and germanium).
25. The detector or detection system of any of the embodiments 1-23, wherein the Te content or composition of the alloy is tuned so that the amorphous alloy has a bandgap providing a photoresponse optimized for any wavelength of electromagnetic radiation in a range of 300 nm through 900 nm, e.g., particularly blue and ultraviolet wavelengths.
26. The detector of any of the embodiments 1-6, or 24 wherein:
the tellurium content and electric field are such that:
a sensitivity (or conversion efficiency) of the detector for the electromagnetic radiation having a wavelength below 450 nm (e.g., 355 nm) is at least as high as for an equivalent detector wherein the only difference is that the active region comprises/consists of non-alloyed amorphous selenium (no tellurium), and
a sensitivity for the wavelengths longer than 450 nm (e.g., 450-900 nm) is higher than can be achieved for the equivalent detector comprising the non-alloyed amorphous selenium.
27. The detector or detection system of any of the embodiments 1-6, wherein the electric field E is in a range of 20 V/μm and 50 V/μm (20 V/μm≤E≤50 V/μm).
28. The detection system of any of the embodiments 7-24, wherein the first direct detector and/or the second indirect detector comprise the detector of any of the embodiments 1-6 or 22-25.

### BRIEF DESCRIPTION OF THE DRAWINGS

Referring now to the drawings in which like reference numbers represent corresponding parts throughout:

FIG. 1. Schematic of a photodetector according to one or more embodiments.

FIG. 2a. Schematic of the setup used for Photothermal Deflection Spectroscopy.

FIG. 2b Absorption coefficient of pure and a-Se e₁₋ₓTₓ thin films, as calculated from PDS measurements. Inset shows Tauc fits to the band edge region.

FIG. 2c. Optical band gaps, E_{g} (red circles, left axis), and Urbach energies, E_{U} (blue triangles, right axis), for a-Se ₁₋ₓTeₓ films.

FIG. 3a. Schematic of the setup used for Transient Photocurrent Time of Flight and Dark/Photocurrent Measurements. FIG. 3b. Schematic of the photodetector during measurement.

FIG. 4 Comparison of hole (filled) and electron (unfilled) mobility at 5 V/μm for a Se₁₋ₓTeₓ devices fabricated in this work (blue triangles) to those of Kasap (1985) and Juhasz (1987) (red circles). The solid lines are inverse exponential fits to [15] and [16] to provide a guide for the eye, with dashed lines the extension of the fit beyond available data.

FIG. 5 Hole and electron mobility as a function of electric field up to 30 V/μm for aSe₁₋ₓTₓ devices fabricated in this work. Hole mobility is highlighted by the top bracket, and electron mobility by the bottom bracket.

FIG. 6a Conversion efficiency of a-Se e₋ₓTeₓ devices under 355 nm light as a function of electric field, up to 30 V/μm.

FIG. 6b. Conversion efficiency of samples with blocking layer at higher concentrations, showing an increase from 0.005% to 1.5% with Te at 635 nm. There is a response at 880 nm from Te alloys, minimal from alloys with only Se. FIG. 6c. External Quantum Efficiency (EQE) and dark current leakage @ 533 nm excitation wavelength, showing much larger EQE response from the 10% Te alloy, relatively low leakage, although the response decreases at higher Te content.

FIG. 7 a) Comparison between Onsager model and experimental results from the conversion efficiency of amorphous Se (355 nm incident light) as a function of electric field, up to 30 V/μm. b) Comparison between Onsager model with field dependent thermalization length and experimental results from the conversion efficiency of amorphous Se—Te samples (355 nm incident light) as a function of electric field, up to 30 V/um. Fit used x=6.3,rₘᵢₙ=0.1 nm, rₘₐₓ=12 nm, and y=4.5*10⁻⁶ cm/V.

FIG. 7c. Measured electron mobility of an amorphous Se—Ge film.

FIG. 8a. Schematic of a dual detector according to one or more embodiments.

FIG. 8b. Close up view of the second indirect detector in FIG. 8a.

FIG. 9. Schematics of the two device architectures fabricated for this work: a) the single pixel a-Se device and b) the multi-pixel FP indirect detector.

FIG. 10. A schematic of the setup used for dark and photocurrent measurements of the single pixel device.

FIG. 11. a) Dark current densities of the single pixel device with a parylene blocking layer compared to one with polyimide ¹² b) Conversion efficiency for the sample in this work and from Abbaszadeh et al. (2012). ¹³c) XRD of a fresh single pixel device and six months after deposition.

FIG. 12. From left to right, various layers deposited for the indirect FPD: the FP readout substrate, the 100 nm parylene planarization layer, amorphous selenium (15 μm), 800 nm of parylene-C blocking layer, and the 75 nm ITO, finished FPD.

FIG. 13. Calculated lag of the FPD based on the signal (inset).

FIG. 14. Noise power spectrum of the FPD imager.

FIG. 15a. (left) Modulated transfer function (MTF) of imager using slant edge technique. (right) Image of resolution phantom demonstrating resolution at 6 line pairs per millimeter.

FIG. 15b. MTF as a function of spatial resolution for the first direct detector.

FIG. 16 (left) PCB board (to scale) and (right) hand phantom with defects highlighted in red.

FIG. 17 is a flowchart illustrating a method of making a detector.

FIG. 18 illustrates a method of making a dual detector comprising a direct detector and an indirect detector.

FIG. 19 is a flowchart illustrating a method of operating a detector.

FIG. 20. Schematic of a system such as an industrial quality control application or medical imager comprising the detection system.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

### Technical Description

### First Embodiment: Selenium Based Detectors

a. Device Structure

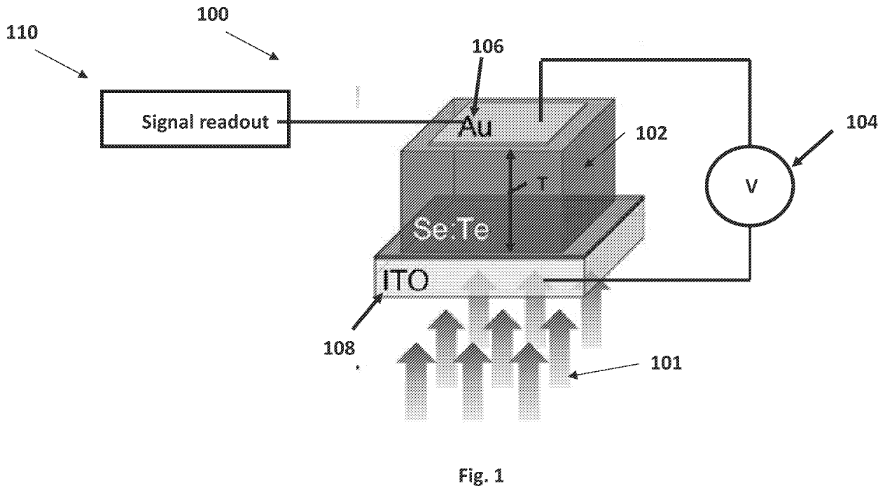

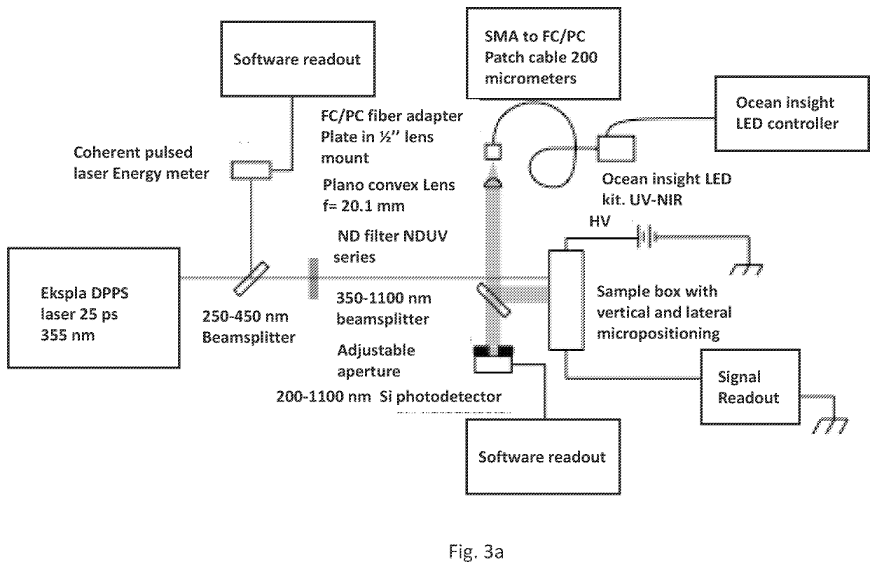

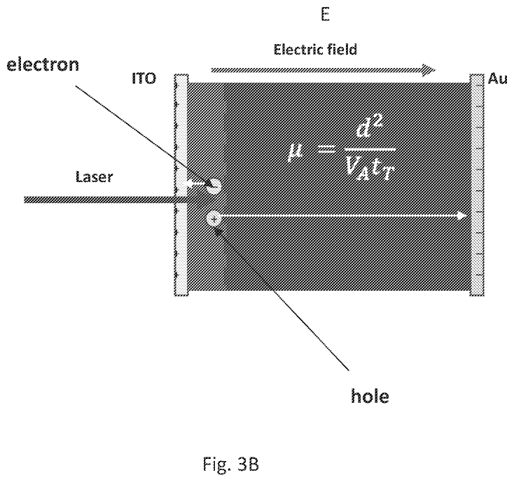

FIG. 1 illustrates a detector 100, comprising an active region 102 comprising an amorphous alloy of selenium and tellurium; and a biasing circuit 104 comprising a first electrical contact 106 and a second electrical contact 108 to the active region; the biasing circuit for applying an electric field E of at least 20 Volts per micrometer (e.g., 20 V/μm≤E≤50 V/μm) across the active region and between the first contact and the second contact. A readout circuit 110 measures a signal (e.g., electrons or holes) in response to irradiation 101 of the active region. The electromagnetic radiation 101 generates electron hole pairs in the active region wherein the signal comprising charge comprising holes or electrons are swept by the electric field to the readout circuit (see also FIG. 3B, for example). The active region can have a thickness (typically less than 50 microns) configured for application of the electric field.

b. Experimental Characterization

### (i) Absorption and Disorder

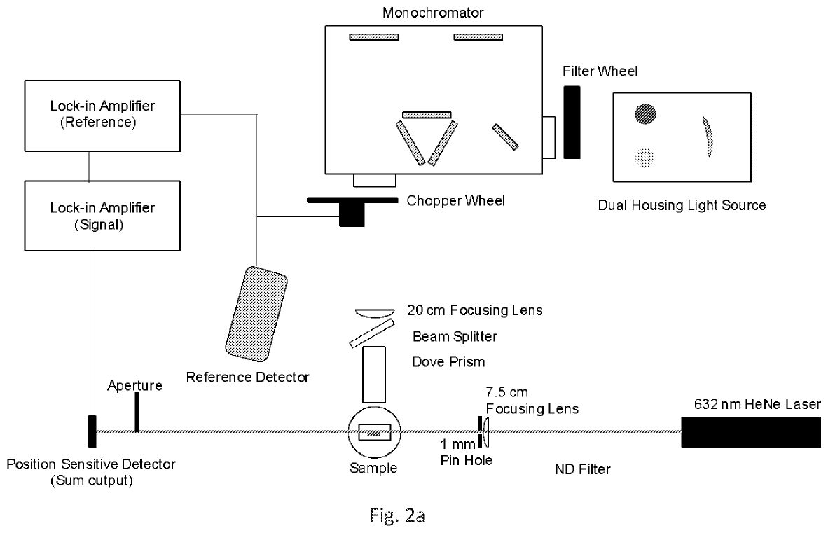

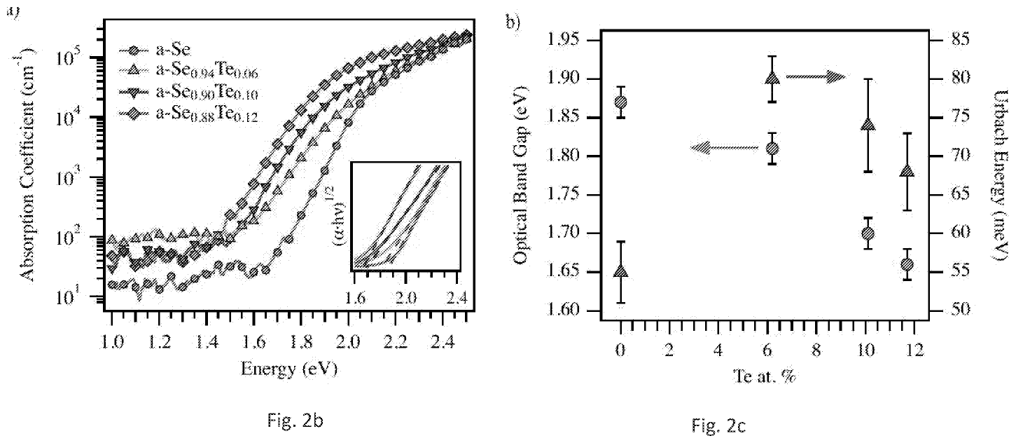

In order to determine disorder and the absorption coefficient, thicker selenium and tellurium films with ˜150 nm thickness were characterized using photothermal deflection spectroscopy (PDS) as illustrated in FIG. 2A. FIG. 2B shows the absorption coefficient calculated from the PDS with Tauc fits shown in the inset. The shift of absorption to lower energies can readily be seen, along with an increase in tail states. FIG. 2C shows the optical band gaps and the Urbach energy—a general measure of disorder—found for each sample. Urbach energies show an increase in disorder with the addition of Te, though we see an initial jump in E_{U} that reduces as the Te content increases. Reddy et al. proposed a band model in which the incorporation of Te leads to the rise of an additional optically active defect energy state just above the conduction edge [18]. This would lead to a rapid increase in the tail absorption with Te inclusion and hence the increase in Urbach energy. As the gap decreases and shallow states begin to overcome the new defect state, the effect on the band edge disorder would be reduced, lowering E_{U}, as we see from PDS fits.

### (ii) Charge Transport

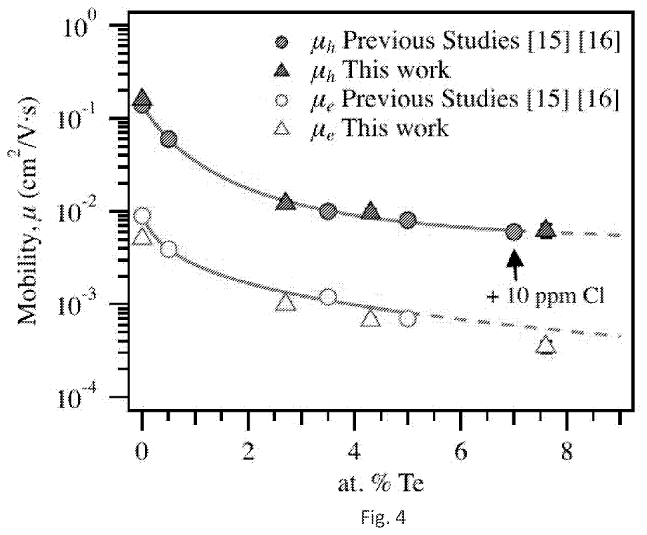

FIG. 3B illustrates a 15 μm thick device used for transient photocurrent time of flight (TOF) measurements using the setup in FIG. 3A. FIG. 4 plots the calculated hole and electron mobilities at 5 V/μm along with a comparison with those found in other studies [15,16]. The hole mobilities found are on par with those found in the other studies [15, 16], demonstrating that the alloys are behaving as expected. Alloying just a small amount (0.5 at. %) of Te results in a halving of the mobility, which can be detrimental to the performance of the device as a photodiode.

Electron mobility follows similar trends to hole mobility. It is important to note that, in contrast to the other studies and the standard for a-Se, the materials characterized here were deposited at room temperature and not at 60-65 C, near the glass transition temperature. It is possible that this resulted in the slight reduction of the electron mobility as compared with [15, 16].

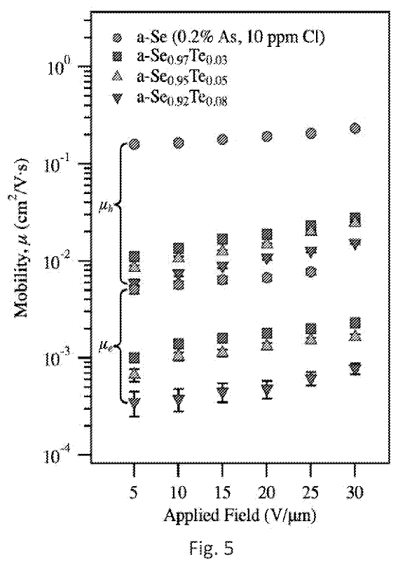

The drop in both electron and hole mobilities has been investigated thoroughly. However, previous studies were performed on samples greater than 50 μm thick and were limited to fields of 10 V/μm or less. Here, the use of thinner films allowed for probing up to 30 V/μm. FIG. 5 shows hole and electron mobility for the a-Se S₋ₓTₓ devices from 5-30 V/μm. Much like for a-Se, the mobilities for the amorphous Se- Te devices increase at higher fields, though at a slightly higher rate.

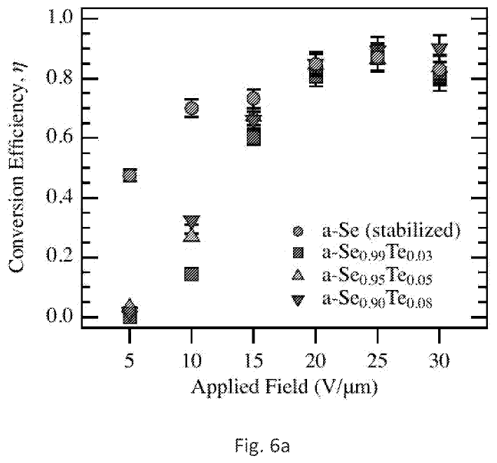

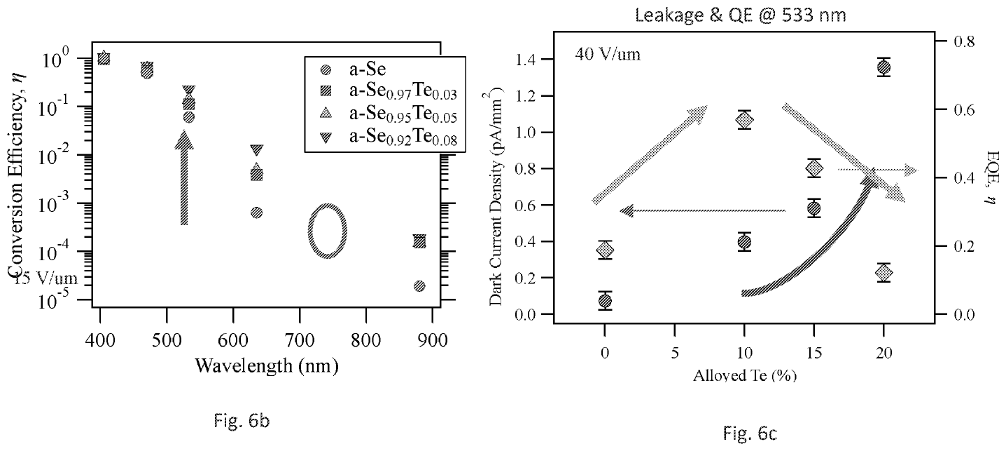

From TOF measurements, conversion efficiency at 355 nm was calculated for each device. Studies show that pure a-Se approaches efficiencies around 80% at 400 nm and 30 V/μm, agreeing within error with our results, reported in FIG. 6 [7]. As may be anticipated from mobility measurements, the efficiency of Te-alloyed samples is much lower than a-Se at low fields; however, increasing the applied field has an increasingly positive effect, with Te-alloyed samples quickly approaching similar efficiencies as for a-Se.

(iii) Quantum Efficiency

It has been commonly accepted that for amorphous selenium the quantum conversion efficiency can be described using a model for electron-hole recombination originally proposed by Onsager [40]. In this model, the incident photon leads to the creation of a bound electron-hole pair with some initial separation given as the thermalization length, r₀ The electron-hole pair can then either recombine or else separate under the effect of the applied field and contribute to current. The charge motion in the Onsager model is treated as Brownian motion of the charge in the presence of the applied field and the Coulomb attraction due to the other photogenerated carrier. The quantum conversion efficiency then depends on both the efficiency of electron-hole creation under illumination and the probability that the generated electron-hole pair will dissociate. In their work, Pai and Enck developed a series expansion for the Onsager quantum efficiency that is slow to converge [7]

A variant of the Onsager model was used to explain the behavior observed in Se—Te devices, the double integral expression developed by Yip et al, where the quantum efficiency, η, can be written as [41]:

$$η = {η}_{0} [ 1 - \frac{1}{2} {\int }_{0}^{2} {e}^{- Cy} dy {\int }_{0}^{D} {I}_{0} ( 2 \sqrt{Cyx} ) ) {e}^{- x} dx ]$$

where C=eEr₀/kT, D=r₀/r₀, and r₀=e²/(4πκε₀KT). In the equations above, η₀ is the pair generation efficiency, taken to be 1, I₀ is the modified Bessel function, e the fundamental charge, E is the electric field, k is the Boltzman constant, T is the temperature, « is the dielectric constant, ε₀ is the permittivity of free space, and r₀ is the critical separation distance. Results in this work were computed via Matlab. This model assumes that the thermalized electron-hole pairs have an initial separation length of r₀. When fit with experiment, this separation length is found to correspond to a particular photon frequency, in which higher frequencies generate a greater separation and achieve higher conversion efficiency at lower fields.

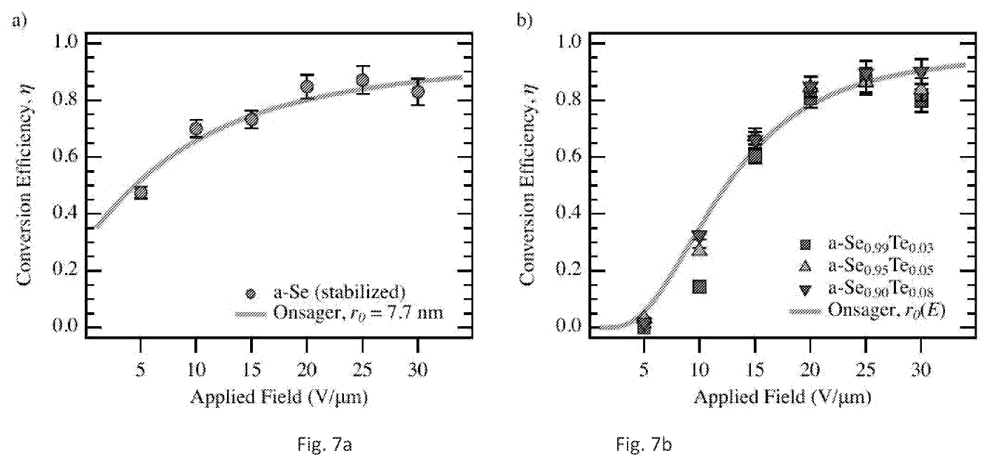

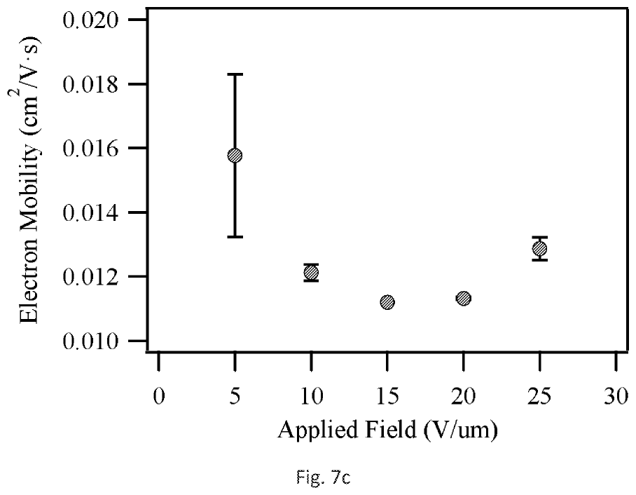

FIG. 7a shows this equation to fit the conversion efficiency data for a-Se for λ=355 nm incident light as a function of applied field. As shown in FIG. 7a, using η₀=1, κ=6.0, and r₀=7.7 nm provides a good match to the experimental data. Pai and Enk determined the thermalization length for several different wavelengths of light in their study and also assumed that η₀=1. If we extrapolate from their results to our smaller wavelength, their model would predict a larger thermalization length, 9.5-10 nm—greater than what we observed. This could be due to the fact that Pai and Enk used pure amorphous Se, whereas we have used stabilized amorphous Se. Alternatively, it could be due to the reduced effect of photon energy on thermalization or relaxation at energies above a certain threshold.

An updated model was also used to fit the field dependence of the quantum conversion efficiency in the Te-doped devices. Initially, we were unable to find a set of parameters that could explain the sharp increase in conversion efficiency with applied field. This likely indicated that the Onsager model was missing some key physics necessary to describe the efficiency of the Se—Te samples.

The thermalization distance is not well defined [7, 42-44]. Dependence of ro on the material diffusion coefficient and mobility is known, and is taken to be constant in Pai and Enck's model. However, diffusion and mobility in a-Se and the Se—Te films vary with applied field, leading to the conclusion that ry has field dependence [10,45]. In addition, effects of large potentials from traps are not incorporated, and a simple form of binding energy is used in the original derivation [7].

To address the issues of the fit, we initially assumed that thermalization length had an exponential dependence on field, r=r₀exp (αE). While using this mathematical form in the Onsager expression does lead to fits to the SeTe sample results, the extracted thermalization lengths at higher fields are extremely large (practically infinite) and non-physical.

To avoid this problem, we assumed that the thermalization length transitions smoothly from a short value at low fields to a larger value at high applied fields. This can be represented mathematically as:

$$r = {r}_{min} + ( {r}_{max} - {r}_{min} ) ( 1 - {e}^{- γ E} )$$

The comparison of the model with the field dependent thermalization length and the Se—Te experimental results is shown in FIG. 7b. Overall, the Onsager model with the field dependent thermalization length is able to describe the experimental trend observed in the Se—Te samples. It is important noting that for the doping range considered (3-8%), the field dependence of all samples is very similar, though we do see a (repeatable) increase in efficiency at lower fields with increasing Te content.

Amorphous selenium is known to operate by a multiple trapping transport mechanism, well described in [46]. As previously discussed, Te dopants lead to the formation of additional trap states in the Se band gap. The addition of a new defect state, for which the energy above the valence edge shrinks with increasing Te, may be responsible for the strong field dependence of the charge dissociation and the slightly increased efficiency with higher Te concentrations for low fields. Carriers may initially have a low probability of escaping until the field strength has bent energy barriers enough to allow tunneling or hopping. This aligns with the observations made in Reddy and Bhatnagar and those made from the Urbach energies in this work [18]. This indicates that the energy of the Te trap state dominates the effects associated with the concentration of the dopants, though higher concentrations may have benefits at low-fields.

### Advantages and Improvements

While hole and electron mobilities up to 8% Te show a drastic reduction compared with a-Se, the data presented herein shows this can be mitigated by operating the devices at fields up to 30 V/pm. At low fields, the efficiencies are significantly reduced with the inclusion of Te; however, the efficiencies increase with higher fields, eventually reaching values comparable to a-Se. Fits to the Onsager model suggest a highly field dependent thermalization length for Se—Te; the addition of a defect state above the valence edge may explain this and the resultant conversion efficiencies, providing further support for the model suggested by Reddy and Bhatnagar. Without being bound by a specific scientific theory, the results presented herein demonstrate the strong potential for amorphous Se—Te in extending the absorption range of a-Se photodetectors and expanding application in indirect X-ray imaging.

Alloying selenium to increase the response to longer wavelengths (>450 nm) is known to deteriorate its response to shorter wavelengths (<450 nm). However, surprisingly and unexpectedly, we demonstrated that by operating the device that is alloyed at higher electric field, one can recover the performance at wavelengths below 450 nm to what is achieved from stabilized selenium (without alloy) at normal operating field (lower field e.g., below 20 V/micron). More specifically, we discovered that if one increases the electric field between 20 V/cm and 50 V/cm, one can recover the sensitivity at lower wavelength, e.g., at 355 nm to levels achievable with stabilized Se only, in addition to having higher sensitivity at long wavelengths (e.g., longer than 450 nm). This is shown in FIG. 6a, plotting the response to 355 nm wavelengths of the alloy contents. It was observed that the sensitivity for the alloy content is at least as high as for the stabilized selenium.

This property is advantageous for detectors comprising a dual layer that has a top layer combined with a bottom layer (scintillator plus selenium detector). In such examples, there is a need to alloy selenium to match the emission of the scintillator with the absorption of selenium containing detector. At the same time, since this scintillator plus selenium detector is a bottom layer, it is more photon starved, and therefore the sensitivity of the selenium containing detector needs to be higher to increase signal to noise ratio. This can be achieved by alloying the selenium with tellurium.

### (iv) Alloying of Ge

Initial studies of evaporation of an alloy of Ge_{0.1}Se_{0.9} resulted in a 6 micron thick Ge_{0.004}Se_{0.996}. Because the Se melting temperature is 220 C, and that for Ge is 938 C evaporation of the Se leaves behind solid Ge and possibly results in an overall drop in electron mobility illustrated in FIG. 7c (although the limited thickness may have resulted in slew rate issues for TOF). Co-deposition of Se and Ge is required to achieve high quality, uniform films.

In one or more embodiments, active regions may comprise amorphous SeₓGe₁₋ₓ or a combined Ge—Se—Te system which may be manufactured using co-deposition and pre-alloyed pellets.

Second Embodiment: Dual Layer Detection system
a. Example Device

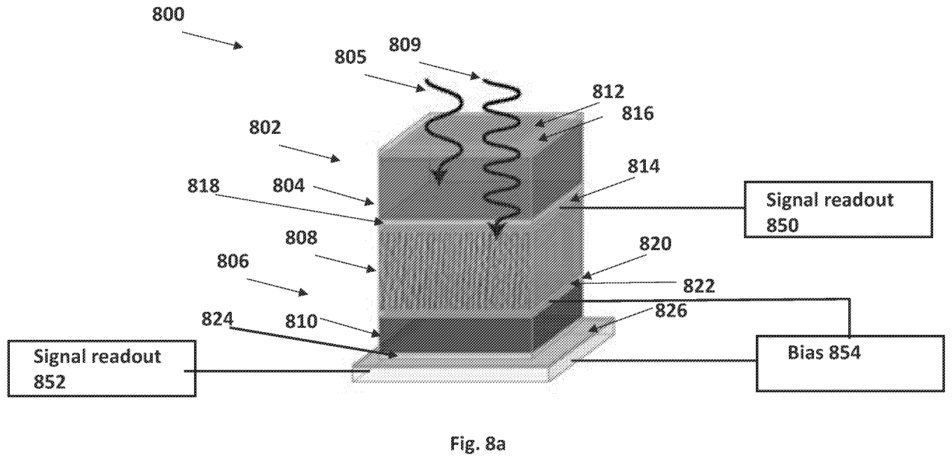

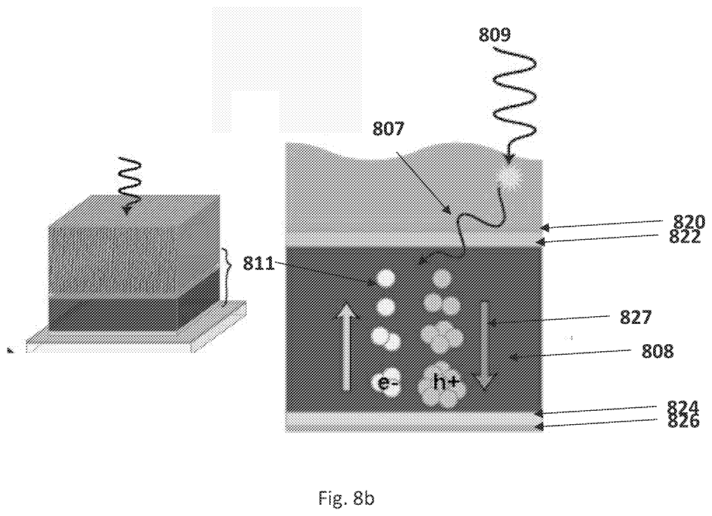

FIG. 8a-8b illustrate an (e.g., X-ray) detection system 800, comprising a first direct detector 802 (e.g., having higher spatial resolution) comprising a first amorphous layer 804 comprising selenium (and optionally tellurium and/or germanium) that outputs first charge (e.g., electrons) in response to first radiation (e.g., X-rays) 805 absorbed in the first amorphous layer and having a first energy, wherein the first charge is used to measure the first incident radiation (e.g., X-rays).

FIGS. 8a-8b further illustrates the system includes a second indirect detector 806 (e.g., with higher gain) under the first direct detector, the second indirect detector comprising a scintillator 808 and a second amorphous layer 810 comprising selenium (and optionally tellurium and/or germanium), wherein the scintillator 808 outputs light/electromagnetic radiation 807 in response to second radiation (e.g., X-rays) 809 transmitted through the first direct detector and absorbed in the second amorphous layer having a second energy higher than the first energy. The second amorphous layer outputs second charge 811 (e.g., electrons e− and/or holes h+) in response to the light/electromagnetic radiation 807 outputted from the scintillator. The second charge is used to measure the second incident radiation (X-rays).

One or more circuits 850, 852 can be electrically coupled to the first direct detector and second indirect detector so as to receive the first charge and the second charge for measuring the radiation (e.g., X-rays).

FIG. 8a illustrates the first direct detector comprises a first electrical contact 812 a second electrical contact 814; a first charge blocking layer 816 between the first amorphous layer and the first electrical contact; a second charge blocking layer 818 between the first amorphous layer and the second electrical contact.

FIG. 8a further illustrates the second indirect detector comprises a third electrical contact 820 under the scintillator; a third charge blocking layer 822 between the second amorphous layer and the third electrical contact; and a fourth charge blocking layer 824 between the second amorphous layer and a fourth electrical contact 826 under the fourth blocking layer.

FIG. 8b illustrates how the third electrical contact 820 and the fourth electrical contact 826 apply a second bias (applied by a biasing circuit 854) forming a second electric field 827 across the second amorphous layer to drive the electrons e− and holes h+ to the third and fourth electrical contacts, respectively for collection and readout.

b. Experimental Characterization

### (i) Device Fabrication

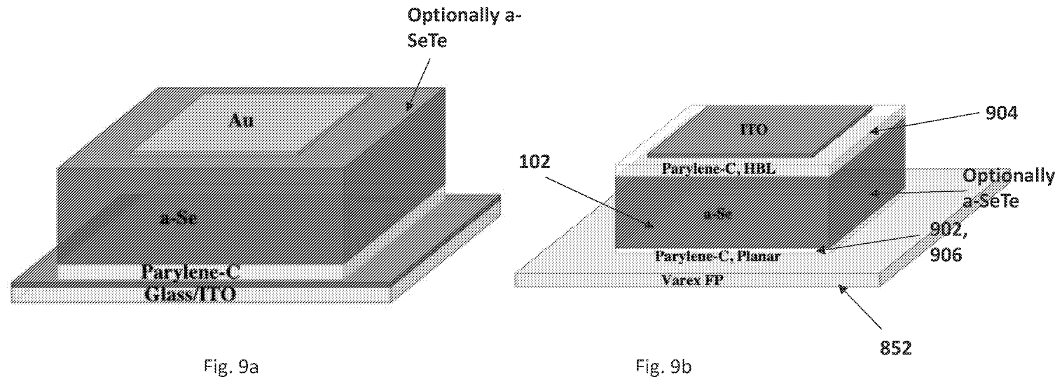

A single pixel detector as illustrated in FIG. 9a was fabricated and tested to verify the performance of the blocking layers. After verifying that the blocking layer used could achieve the required low leakage, photocurrents, and conversion efficiency, the indirect flat panel detector (FPD) in FIG. 9b was fabricated.

The single pixel device illustrated in FIG. 9a was fabricated by depositing parylene-C on ITO/glass substrates, followed by stabilized a-Se and a gold top contact. ITO/glass slides were cleaned by ultrasonication in acetone and isopropyl alcohol for 10 minutes each, then rinsed with DI water and dried with nitrogen. Parylene-C was deposited by vapor deposition using a PDS 2010 Labcoter 2 parylene deposition system (Specialty Coatings), resulting in a 750 nm layer of parylene. A 15 um layer of stabilized a-Se (Amalgamet) was deposited by thermal evaporation at a rate of 105 Å/s at room temperature. Finally, a 100 nm layer of Au was deposited by electron beam evaporation.

The a-Se indirect FP detector of FIG. 9b was similarly fabricated, with slight modifications to the ordering of layers and the top contact material. A Si thin film transistor (TFT) substrate with 85 mm×85 mm active area was provided by Varex Imaging Corporation. A 100 nm planarization layer of parylene-C was deposited on the FP substrate to prevent crystallization of the a-Se. After deposition of 15 um a-Se, a 750 nm layer of parylene-C was deposited, followed by a 75 nm sputtered layer of ITO to serve as a transparent contact.

To ensure no crystallization resulted from the parylene layer, X-ray diffraction (XRD) was performed after deposition and after six months of the device sitting in the dark in a dry environment.

### (ii) Leakage and Conversion Efficiency Characterization

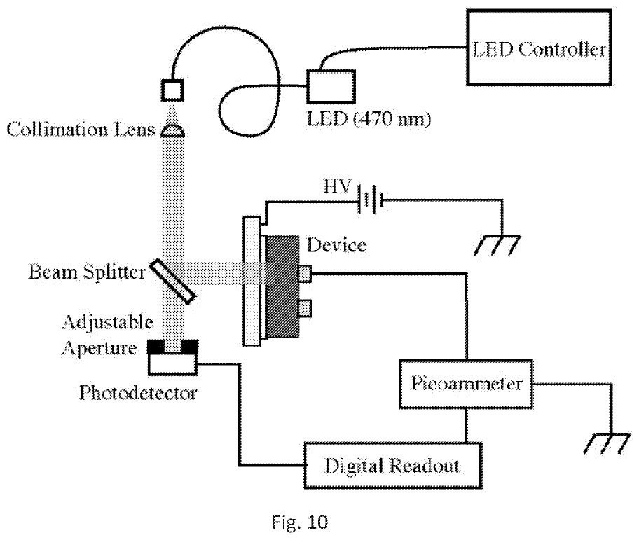

Dark and photocurrent measurements using the setup of FIG. 10 were performed on the single pixel devices to estimate the conversion efficiency when parylene-C is used as a hole blocking layer. The dark current and photocurrent measurements were taken with a Keithley 6487 picoammeter and readout by Kickstart 2 software. The device was held at each bias voltage for 15 minutes in the dark to allow any accumulated charge to dissipate and for the detector to reach a steady-state. Photocurrent measurements were performed by shining a collimated 470 nm LED (Ocean Insight) on the device for 15 seconds. The beam was split between the device and a Si photodiode (Thorlabs), which had an adjustable aperture to match the size of the device under test, allowing for LED intensity measurement concurrent with photocurrent measurements. From these measurements, the conversion efficiency, η, was calculated using:

$$η = \frac{( {I}_{p} - {I}_{D} ) * C}{{P}_{I} * {E}_{λ}}$$

where I_{P} is the photocurrent, I_{D} is the dark current, C is the value of 1 Coulomb (6.24E-18 electrons/Coulomb), P_{I} is the LED power incident on the device area, and E_{λ} is the energy of the 470 nm LED (254.52 KJ/mol).

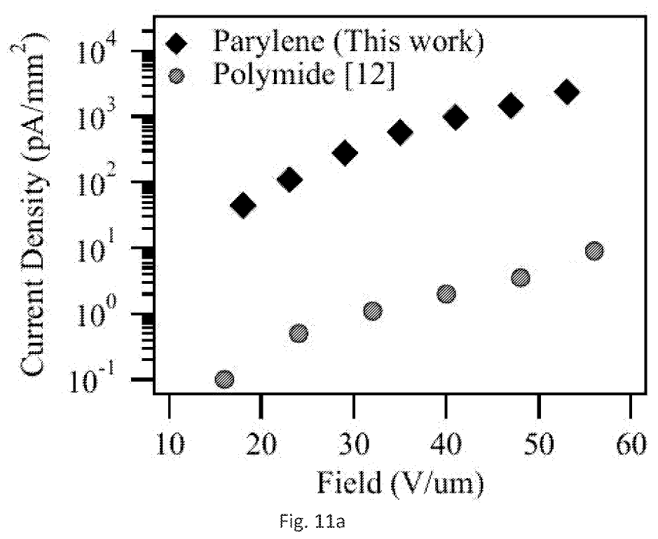

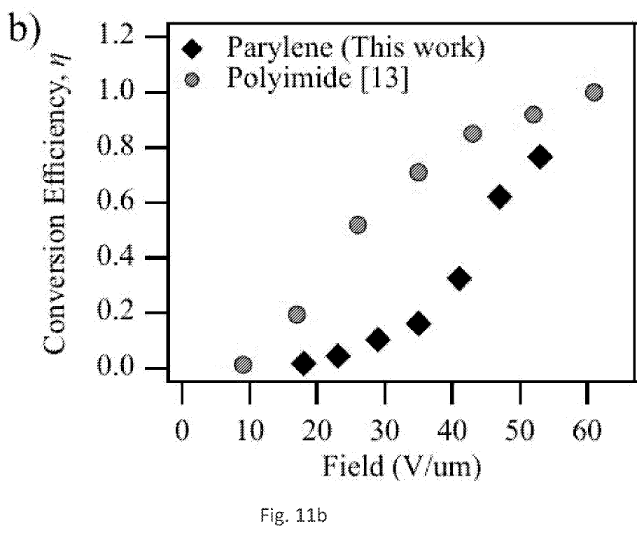

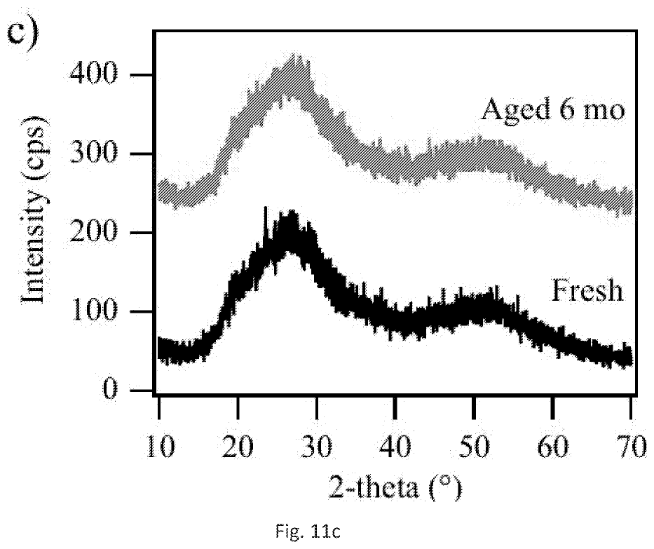

FIG. 11a plots the dark current density as a function of applied field for the single pixel detector, along with data for a typical device with a polyimide blocking layer for comparison ¹² While the dark current is not as low as that of polyimide, it still allows biasing of the device up to 50 V/um, more than sufficient for preliminary tests of the indirect FPD.

FIG. 11b plots the conversion efficiency for the single pixel device and a polyimide for comparison ¹³ The parylene device displays poor performance at lower voltages, however recovers at fields above 40 V/um. The efficiency is still about 10% lower than that of a typical polyimide device, but is reasonable for the unoptimized structure and operation at 50 V/um—the intended field for the FPD.

FIG. 11c shows the XRD scans of a device within a week a fabrication and another aged 6 months after testing. Both scans show amorphous behavior in the device, indicated by the broad, low intensity peaks around 28 deg and 52 deg. It is important for the FPD to remain stable over an extended period, as the time between initial fabrication and testing is variable.

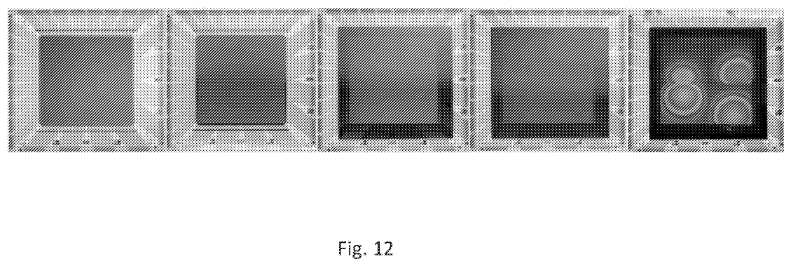

FIG. 12 shows images of the indirect a-Se FPD at each manufacturing step. The small vertical and horizontal lines across the ITO layer of the FPD were caused by an overlap of four ITO depositions, as only 1.5″ squares of ITO could be deposited at a time due to ITO target size constraints. This may have a small impact on the device performance in the pixels containing these regions of thicker ITO.

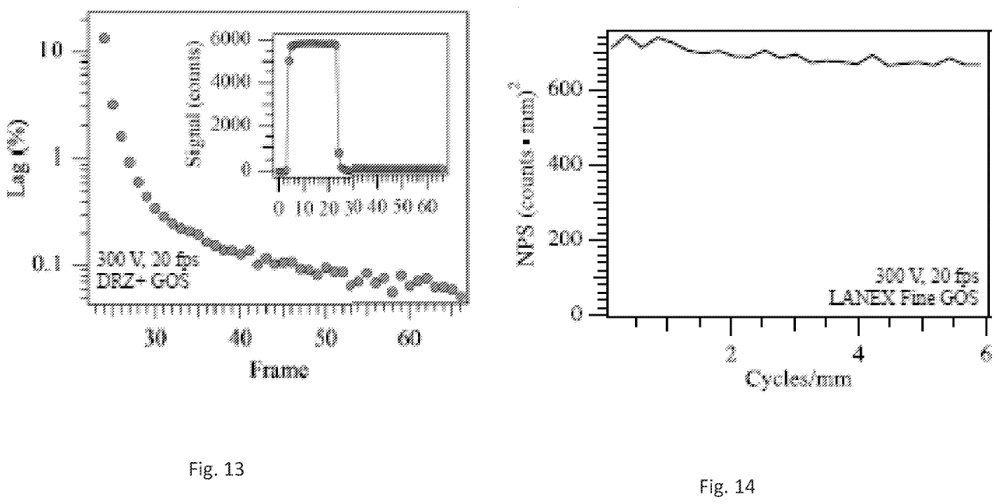

FIG. 13 shows the signal from the detector is steady at just under 6000 counts over 20 frames. The imager conversion efficiency is ˜12%, in line with expected light attenuation and a-Se QE at 18 V/um. Lag drops from 13.34% to 3.15% in the 2 frames after exposure, then <1% in 4 frames.

FIG. 14 shows the detector shows good noise power spectrum (NPS) at 300 V bias and 35 uGy/frame, under 700 counts2 mm2 at 6 lp/mm.

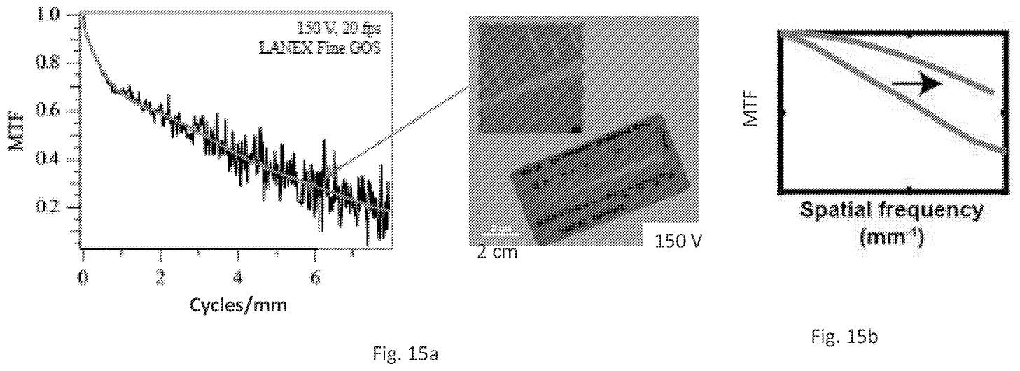

FIG. 15a shows the imager has an MTF in line with the performance of the scintillator used, with resolution up to 6 lp/mm.

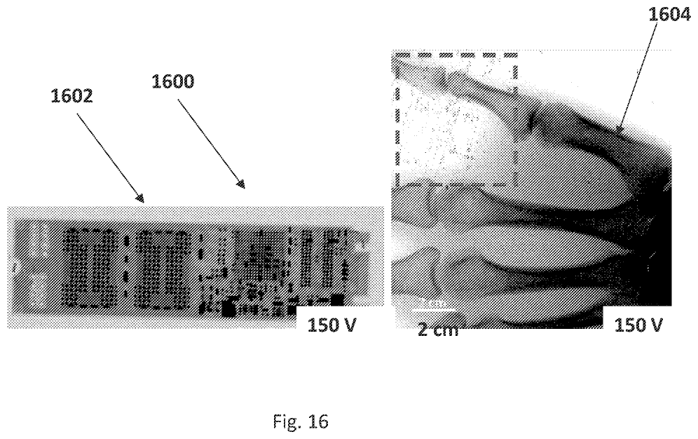

FIG. 16 illustrates images of a PCB board and hand phantom obtained using the FPD detector.

### Process Steps

### Direct Detector

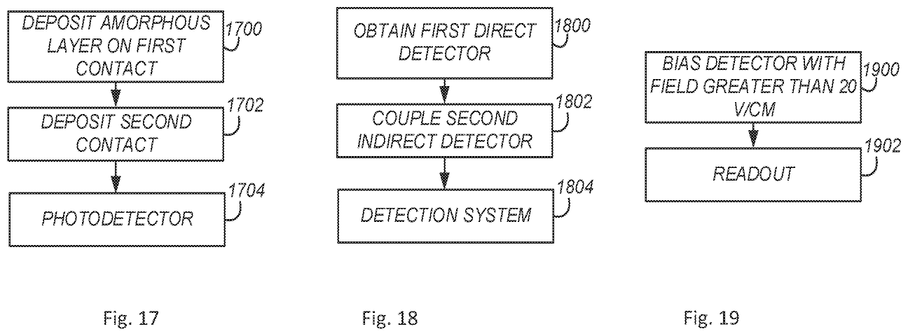

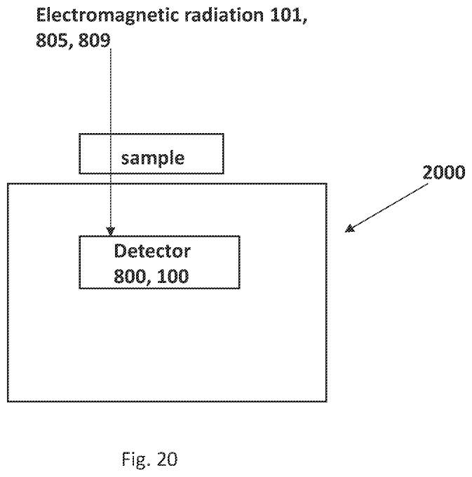

FIG. 17 is a flowchart illustrating a method of making a detector.

Block 1700 represents depositing an active layer comprising an amorphous alloy of selenium and tellurium (and optionally germanium) on a substrate such as, but not limited to, a glass substrate, a substrate comprising thin film transistors (TFT), a readout circuit, a flat panel detector, or an X-ray imaging device (e.g., real time digital imaging device such as a Varex flat panel detector). In typical embodiments, the active layer is deposited on a first electrical contact (e.g., transparent electrical contact layer, such as indium tin oxide (ITO) which has already been deposited on the substrate. The transparent electrical contact layer is transparent for the electromagnetic radiation (e.g. blue or ultraviolet wavelengths) being detected by the active layer. In yet further examples, the active layer is deposited on a first charge blocking layer (e.g., electron or hole blocking layer) which has already been deposited on the transparent electrical contact layer on the substrate. The depositing can comprise evaporation or a co-deposition method, for example.

The amount of tellurium can be tuned to obtain the desired bandgap for detecting the electromagnetic radiation (e.g., blue, ultraviolet, or X-ray wavelengths, or any wavelength between 400 nm and 900 nm).

Block 1702 represents depositing a second electrical contact on the active layer. In some embodiments, a second charge blocking layer (e.g., hole or electron blocking layer, blocking charge of opposite polarity to that formed in Block 1700) is deposited on the active layer and the second electrical contact is deposited on the second charge blocking layer. Examples of the second electrical contact layer include, but are not limited to, a transparent electrical contact such as ITO or a metal layer.

Block 1704 represents the end result, a detector. The typical detection process comprises the electromagnetic radiation exciting an electron from the valence band across the bandgap to form an electron hole pair. The electron and holes are separated by an electric field applied across the contacts, such that the electric field drives the holes to the first electrical contact and the electrons to the second electrical contact (or vice versa if the charge blocking layers are inverted). A readout circuit comprising the first electrical contact or the second electrical contact can be provided to readout the signal in response to the electromagnetic radiation. A biasing circuit can be provided to apply the electric field across the first electrical contact and the second electrical contact.

### Imager

FIG. 18 illustrates a method of making an imager.

Block 1800 represents obtaining or manufacturing a first direct detector comprising a first amorphous layer comprising selenium (and optionally tellurium and/or germanium) that outputs first charge (e.g., electrons) in response to first electromagnetic radiation (e.g., X-rays) absorbed in the first amorphous layer and having a first energy, wherein the first charge is used to measure the first incident electromagnetic radiation (e.g., X-rays). In one embodiment, fabricating the first direct detector comprises depositing a first charge blocking layer on a first electrical contact on a substrate, a first amorphous layer on the first charge blocking layer, a second charge blocking layer on the first amorphous layer, and a second electrical contact on the second charge blocking layer.

Block 1802 represents coupling a second indirect detector under the first direct detector, the second indirect detector comprising a scintillator and a second amorphous layer comprising selenium (and optionally tellurium). The scintillator outputs light in response to second electromagnetic radiation (e.g., X-rays) transmitted through the first direct detector and absorbed in the second amorphous layer having a second energy higher than the first energy, and the second amorphous layer outputs second charge (e.g., electrons) in response to the light outputted from the scintillator. As described herein, the second charge is used to measure the second incident radiation (e.g., X-rays); and one or more circuits electrically coupled to the first direct detector and second indirect detector so as to receive the first charge and the second charge for measuring the X-rays.

The scintillator can be any medium that re-emits or generates electromagnetic radiation in a different wavelength range from, and in response to, the second electromagnetic radiation. E.g., the medium could be a luminescent material, a phosphor for example. In typical examples, Scintillators are materials that can alter high-energy radiation, for example, X- or γ-rays to a near-visible or visible light.

In one or more embodiments, fabricating the second indirect detector comprises depositing the second amorphous layer on a fourth charge blocking layer on a fourth electrical contact; the third charge blocking layer on the second amorphous layer; and a third electrical contact on the third charge blocking layer; and the scintillator on the third electrical contact.

Method of operating

FIG. 19 illustrates a method of operating the detector of FIG. 17 or 18, comprising the following steps.

Block 1900 represents biasing each of the amorphous layer(s) with an electric field, e.g., of at least 20 volts per micrometer or at least 20 volts per micrometer.

Block 1902 represents reading out a photocurrent or other readout signal from the detectors or imagers in response to electromagnetic radiation.

### Device, System, and Method Embodiments

Illustrative embodiments of the present invention include, but are not limited to, the following (referring also to FIGS. 1-19).
1. A detector 100 for electromagnetic radiation 101, comprising:
an active region 102 comprising an amorphous alloy comprising selenium and tellurium; and
a biasing circuit 104 comprising a first electrical contact 106 and a second electrical contact 108 to the active region, the biasing circuit for applying an electric field of at least 20 Volts per micrometer between the first contact and the second contact and across the active region.
2 The detector of embodiment 1, wherein the active region comprises less than 12% tellurium.
3. The detector of embodiment 1 or 2, wherein the active region comprises or consists essentially of amorphous Se₁₋ₓTeₓ with 0.03≤x≤0.12.
4. The detector of any of the embodiments 1-3, wherein a thickness T of the active region between the first contact and the second contact is less than 50 micrometers.
5. The detector of any of the embodiments 1-4, wherein the electric field is in a range of 20 volts per micrometer-30 Volts per micrometer and/or in a range wherein quantum efficiency of the detector for detecting the electromagnetic radiation 101 having a wavelength corresponding to ultraviolet wavelengths or blue wavelengths is in a range of 80%-100%.
6. The detector of any of the embodiments 1-5, further comprising a readout circuit 110 comprising the first electrical contact 106 or the second electrical contact 108, for measuring a photocurrent (e.g. comprising charge comprising holes or electrons) generated in response to electromagnetic radiation irradiating the active region in a presence of the electric field.
7. An (e.g., X-ray) detection system 800, comprising:
a first direct detector 802 comprising a first amorphous layer 804 comprising selenium that outputs first charge (e.g., electrons) in response to first electromagnetic radiation (e.g., X-rays) 805 absorbed in the first amorphous layer 804 and having a first energy, wherein the first charge is used to measure the first incident electromagnetic radiation (e.g., X-rays); and
a second indirect detector 806 under the first direct detector, the second indirect detector comprising a scintillator 808 and a second amorphous layer 810 comprising selenium, wherein:
the scintillator outputs light in response to second electromagnetic radiation (e.g., X-rays) 809 transmitted through the first direct detector and absorbed in the second amorphous layer 810 and having a second energy higher than the first energy,
the second amorphous layer 810 outputs second charge (e.g., electrons) in response to the light outputted from the scintillator, and
the second charge is used to measure the second incident electromagnetic radiation (e.g., X-rays); and
optionally one or more circuits 850, 852 electrically coupled to the first direct detector and second indirect detector so as to receive the first charge and the second charge for measuring the electromagnetic radiation (e.g., X-rays).
8. The detection system of embodiment 7, wherein at least one of the first amorphous layer 804 or the second amorphous layer 810 comprise an alloy of selenium and tellurium.
9. The system of embodiment 8, wherein the alloy comprises or consists essentially of at least 60% selenium and tellurium as the remainder (e.g., tellurium in a range of 1-40%, can be optionally graded).
10. The system of embodiment 7, wherein the first energy is such that at least 50% of the photons of the first absorbed electromagnetic radiation (e.g., X-rays) each have an energy below 50 keV (e.g., 5-50 keV) and the second energy is such that at least 50% of the photons of the second absorbed electromagnetic radiation (e.g., X-rays) have an energy above 50 keV.
11. The system of any of the embodiments 7-10, wherein:
the first direct detector comprises:
   a first electrical contact 812;
   a second electrical contact 814;
   a first charge blocking layer 816 between the first amorphous layer and the first electrical contact;
   a second charge blocking layer 818 between the first amorphous layer and the second electrical contact; and
the second indirect detector comprises:
   the scintillator 808;
   a third electrical contact 820 under the scintillator;
   a third charge blocking layer 822 between the second amorphous layer and the third electrical contact; and
   a fourth charge blocking layer 824 between the second amorphous layer and a fourth electrical contact 826 under the fourth blocking layer.
12. The system of embodiment 11, wherein each of the blocking layers comprise:
an electron blocking layer or a hole blocking layer; and
at least one of parylene, polyimide, hafnium oxide, aluminum oxide, or antimony disulphide (for the electron blocking layer).
13. The system of embodiment 11 or 12, further comprising the one or more circuits comprising:
a first readout circuit 850 comprising at least one of the first electrical contact or the second electrical contact, for reading out the first charge, and
a second readout circuit 852 comprising at least one of the third electrical contact or the fourth electrical contact, for reading out the second charge.
14. The detection system of embodiment 13, wherein at least one of the readout circuits 852 is configured as a pixel array or imager for forming one or more images 1600 using at least the first charge or the second charge.
15. The detection system of embodiment 14, wherein the at least one readout circuit 852 comprises transistors arranged in the pixel array to form a thin film transistor flat panel that generates signals from the first charge and/or the second charge so that the signals can be processed to form the one or more images 1600.
16. The detection system of any of the embodiments 14 or 15, wherein the first energy and the second energy are such that the second charge and the first charge can be used to differentiate, in the one or more images, different materials or densities in a sample 1602 that interacted with the electromagnetic radiation (e.g., comprising X-rays) prior to detection using the detection system.
17. The detection system of embodiment 16, wherein the different materials are soft and hard tissue 1604 or different amounts of calcification.
18. A particle physics detection system or industrial quality control system 2000 comprising the detection system of any of the embodiments 1-16.
19. A medical imager 2000 for imaging human tissue comprising the detection system of any of the embodiments 1-17.
20. The detection system 800 of any of the embodiments 7-19, wherein the first direct detector is stacked on top of the second indirect detector and each of the first direct detector and the second indirect detector are formed on a base 902 that maintains the first amorphous layer and the second amorphous layer, respectively, in an amorphous state.
21. The detection system of any of the embodiments 11-20, wherein:
the first electrical contact and the second electrical contact apply a first bias (applied by a biasing circuit) forming a first electric field across the first amorphous layer, and
the third electrical contact and the fourth electrical contact apply a second bias (applied by a biasing circuit 854) forming a second electric field across the second amorphous layer, and
the first electric field is at least 10 V/micron, and
the second electric field is at least 20 V/micron.
22. The detection system of embodiment 21, wherein the second amorphous layer comprises tellurium.

The detection of any of the embodiments 1-22, wherein the amorphous layer, or the selenium of the first amorphous layer and/or the second amorphous layer is stabilized selenium or a stabilized layer comprising 5-20 ppm chlorine and optionally comprises 0.2%-0.5% arsenic.
23. The detection system of any of the embodiments 7-23, wherein at least one of the second amorphous layer or the first amorphous layer does not comprise tellurium and arsenic.
24. The detector or detection system of any of the embodiments 1-23, wherein one or more of the amorphous layers comprise germanium (e.g., comprise an alloy of selenium and at least one of tellurium and germanium).
25. The detector or detection system of any of the embodiments 1-24, wherein the Te content or composition of the alloy is tuned so that the amorphous alloy has a bandgap providing a photoresponse optimized for any wavelength of electromagnetic radiation in a range of 300 nm through 900 nm, e.g., particularly blue and ultraviolet wavelengths.
26. The detector 100 of any of the embodiments 1-6, wherein:
a first charge blocking layer 904 (e.g., hole or electron blocking layer) is between the amorphous layer and the first electrical contact;
a second charge blocking layer (e., electron or hole blocking layer, opposite polarity to that in first charge blocking layer) is between the amorphous layer and the second electrical contact.
27. The detector of any of the claim 1-6 or 26, wherein the tellurium content and electric field are such that the sensitivity for electromagnetic radiation having a wavelength below 450 nm (e.g., 355 nm) is at least as high as for the equivalent detector wherein the active region comprises/consists of amorphous selenium (a-Se, no tellurium) [detectors otherwise equivalent], while maintaining a broadband sensitivity for wavelengths longer than 450 nm (e.g., higher than that can be achieved for non-alloyed amorphous selenium (a-Se).
28. The detection system of any of the claim 1-6 or 27, wherein the readout circuit 110, 852 is configured as a pixel array or imager for forming one or more images 1600 using the charge (electrons or holes) generated by the electromagnetic radiation 101.
29. The detection system of embodiment 28, wherein the readout circuit 852 comprises transistors arranged in the pixel array to form a thin film transistor flat panel that generates signals from the first charge and/or the second charge so that the signals can be processed to form the one or more images 1600.
30. The systems of any of the embodiments 16-19 comprising the detector of any of the embodiments 1-6 or 26-29.
31. The detector of any of the embodiments 1-6 or 26-30 wherein the amorphous layer is formed on a base 902 that maintains the amorphous layer in an amorphous state and/or the amorphous layer comprises a stabilizer (e.g. arsenic) that maintains the amorphous layer in an amorphous layer so that the amorphous layer comprises a stabilized amorphous layer.
32. The detector or detection system of any of the embodiments 1-6, wherein the electric field E is in a range of 20 V/μm and 50 V/μm (20 V/μm≤E≤50 V/μm).
33. The detection system of any of the embodiments 7-24, wherein the first direct detector and/or the second indirect detector comprise the detector of any of the embodiments 1-6 or 22-25.
34. The detection system of any of the embodiments 7-33, wherein the first direct detector (top layer) has higher spatial resolution and the second indirect detector (bottom layer) has higher gain.

### REFERENCES

The following references are incorporated by reference herein
[1] Kasap, S., Frey, J. B., Belev, G., Tousignant, O., Mani, H., Laperriere, L., Reznik, A., Rowlands, J. A.: Amorphous selenium and its alloys from early xeroradiography to high resolution X-ray image detectors and ultrasensitive imaging tubes 246(8), 1794-1805. https://doi.org/10.1002/pssb. 200982007
[2] Reznik, A., Baranovskii, S. D., Rubel, O., Juska, G., Kasap, S. O., Ohkawa, Y., Tanioka, K., Rowlands, J. A.: Avalanche multiplication phenomenon in amorphous semiconductors: Amorphous selenium versus hydrogenated amorphous silicon 102(5), 053711. https://doi. org/10.1063/1.2776223
[3] Huang, H., Abbaszadeh, S.: Recent Developments of Amorphous Selenium-Based X-Ray Detectors: A Review 20(4), 1694-1704. https://doi.org/10.1109/JSEN.2019.2950319
[4] Hellier, K., Benard, E., Scott, C. C., Karim, K. S., Abbaszadeh, S.: Recent Progress in the Development of a-Se/CMOS Sensors for X-ray Detection 5(4), 29. https://doi.org/10.3390/qubs5040029
[5] Allec, N., Abbaszadeh, S., Karim, K. S.: Single-layer and dual-layer contrast-enhanced mammography using amorphous selenium flat panel detectors 56(18), 5903-5923. https://doi.org/10.1088/0031-9155/56/18/009
[6] Tabak, M. D.: Photogeneration Effects in Amorphous Selenium 8(S1), 4-7
[7] Pai, D. M., Enck, R. C.: Onsager mechanism of photogeneration in amorphous selenium 11(12), 5163-5174. https://doi.org/10.1103/PhysRevB. 11.5163
[8] A Microfabricated, Low Dark Current a-Se Detector for Measurement of Microplasma Optical Emission in the UV for Possible Use on-Site”. “Paper presented at Next-Generation Spectroscopic Technologies VI
[9] Mandal, K. C., Mehta, A., Chaudhuri, S. K., Cui, Y., Groza, M., Burger, A.: Characterization of Amorphous Selenium Alloy Detectors for X-Rays and High Energy Nuclear Radiation Detection. International Society for Optics and Photonics. “Paper presented at Hard X-Ray, Gamma-Ray, and Neutron Detector Physics XV”. https://doi.org/10.1117/12.202713
[10] Kasap, S. O., Juhasz, C.: Time-of-flight drift mobility measurements on chlorine-doped amorphous selenium films 18(4), 703. https://doi.org/10. 1088/0022-3727/18/4/015
[11] Seok, D. W., Choi, J. Y., Kang, S. S., Jang, G. W., Mun, C. W., Nam, S. H.: New CsI:Na-selenium X-Ray Detector. International Society for Optics and Photonics. “Paper presented at Medical Imaging 2004: Physics of Medical Imaging”. https://doi.org/10.1117/536200
[12] Lanyon, H. P. D.: Optical and Electrical Properties of Selenium-Tellurium Alloys 35, 1516-1523. https://doi.org/10.1063/1.1713659
[13] Watanabe, H., Kao, K. C.: Structure and Properties of Se₁₋ₓTeₓ Films 18(9), 1849-1850. https://doi.org/10.1143/JJAP.18.1849
[14] Park, W.-D., Tanioka, K.: Spectral Responses of Te-Doped a-Se HighGain Avalanche Rushing Amorphous Photoconductor (HARP) Films for a Solid State Image Sensor 42, 1954. https://doi.org/10.1143/JJAP. 42. 1954
[15] Kasap, S. O., Juhasz, C.: Charge transport in chlorine doped amorphous Se:Te xerographic photoreceptor films 72(1), 23-37. https://doi.org/10. 1016/0022-3093(85)90162-0
[16] Juhasz, C., Vaezi-Nejad, M., Kasap, S. O.: Xerographic properties of single- and double-layer photoreceptors based on amorphous seleniumtellurium alloys 22(7), 2569-2582. https://doi.org/10.1007/BF1082147
[17] Silva, L. A., Cutler, M.: Optical properties of liquid Se-Te alloys 42(11), 7103-7113. https://doi.org/10.1103/PhysRevB. 42.7103
[18] Reddy, K. V., Bhatnagar, A. K.: Electrical and optical studies on amorphous Se-Te alloys 25(12), 1810-1816. https://doi.org/10.1088/0022-3727/25/12/017
[19] Vermeulen, P. A., Momand, J., Kooi, B. J.: Reversible amorphouscrystalline phase changes in a wide range of Se₁₋ₓTeₓ alloys studied using ultrafast differential scanning calorimetry 141(2), 024502. https://doi.org/10.1063/1.4886185
[20] Hadar, I., Hu, X., Luo, Z. -Z., Dravid, V. P., Kanatzidis, M. G.: Nonlinear Band Gap Tunability in Selenium-Tellurium Alloys and Its Utilization in Solar Cells 4(9), 2137-2143. https://doi.org/10.1021/acsenergylett. 9b01619
[21] Yang, M., Zhu, H., Yi, W., Li, S., Hu, M., Hu, Q., Du, B., Liu, X., Su, T.: Electrical transport and thermoelectric properties of Te-Se solid solutions 383(22), 2615-2620. https://doi.org/10.1016/j.phyleta.2019.05.019
[22] Tan, C., Amani, M., Zhao, C., Hettick, M., Song, X., Lien, D. -H., Li, H., Yeh, M., Shrestha, V. R., Crozier, K. B., Scott, M. C., Javey, A.: Evaporated SeₓTe₁₋ₓ Thin Films with Tunable Bandgaps for Short-Wave Infrared Photodetectors 32(38), 2001329. https://doi.org/10.1002/adma. 202001329
[23] Dawar, A. L., Joshi, J. C., Narain, L.: Electrical and optical properties of Se₁₋ₓTeₓ films 76(2), 113-118. https://doi.org/10.1016/0040-6090(81) 90242-X
[24] Kessler, F. R., Sutter, E.: Absorption and Photoconductivity of a Series of Selenium-Tellurium Mixed Crystals 23(1), 25-33. https://doi.org/10. 1002/pssb. 19670230152
[25] Bhatnagar, A. K., Subrahmanyam, S. V.: Photoacoustic study of crystalline Se₁₋ₓTeₓ semiconducting alloys 42(4), 281-286. https://doi.org/10.1016/0038-1098(82)90543-9
[26] Takahashi, T.: Drift mobilities in amorphous As—Se—Te 34(3), 307-312. https:/doi.org/10.1016/0022-3093(79)90017-6
[27] Polischuk, B., Kasap, S. O., Aiyah, V., Scansen, D., Bekirov, A.: Charge carrier trapping in chalcogenide semiconductors 137-138, 943-946. https: //doi.org/10.1016/S0022-3093(05)80276-5
[28] Kresse, G., Furthmüller, J.: Efficiency of ab-initio total energy calculations for metals and semiconductors using a plane-wave basis set 6(1), 15-50. https://doi.org/10.1016/0927-0256(96)00008-0
[29] Kresse, G., Furthmüller, J.: Efficient iterative schemes for ab initio totalenergy calculations using a plane-wave basis set 54(16), 11169-11186. https://doi.org/10.1103/PhysRevB.54.11169
[30] Holmström, E., Bock, N., Peery, T., Chisolm, E., Lizárraga, R., De Lorenzi-Venneri, G., Wallace, D.: Structure discovery for metallic glasses using stochastic quenching 82(2), 024203. https://doi.org/10. 1103/PhysRevB. 82.024203
[31] Amézaga, A., Holmström, E., Lizárraga, R., Menéndez-Proupin, E., Bartolo-Pérez, P., Giannozzi, P.: Quantitative local environment characterization in amorphous oxides 81(1), 014210. https://doi.org/10.1103/PhysRevB.81.014210
[32] Århammar, C., Pietzsch, A., Bock, N., Holmström, E., Araujo, C. M., Gråsjö, J., Zhao, S., Green, S., Peery, T., Hennies, F., Amerioun, S., Föhlisch, A., Schlappa, J., Schmitt, T., Strocov, V. N., Niklasson, G. A., Wallace, D. C., Rubensson, J. -E., Johansson, B., Ahuja, R.: Unveiling the complex electronic structure of amorphous metal oxides 108(16), 63556360. https://doi.org/10.1073/poas. 1019698108
[33] Krukau, A. V., Vydrov, O. A., Izmaylov, A. F., Scuseria, G. E.: Influence of the exchange screening parameter on the performance of screened hybrid functionals 125(22), 224106. https://doi.org/10.1063/1.2404663
[34] Read, J. C., Stewart, D. A., Reiner, J. W., Terris, B. D.: Evaluating Ovonic Threshold Switching Materials with Topological Constraint Theory 13(31), 37398-37411. https://doi.org/10.1021/acsami.1c10131
[35] Farahmandzadeh, M., Marcinko, S., Jaramillo, C., Cheng, M. K., Curreli, D., Abbaszadeh, S.: Simulation and Experimental Validation of the Uniformity of Thermally Evaporated Amorphous Selenium Films for Large-Area Imaging and Radiation Detection Applications 68(2), 626-631. https://doi.org/10.1109/TED.2020.3045963
[36] Jackson, W. B., Amer, N. M., Boccara, A. C., Fournier, D.: Photothermal deflection spectroscopy and detection 20(8), 1333-1344. https://doi.org/10.1364/AO.20.001333
[37] Jackson, W. B., Amer, N. M.: Direct measurement of gap-state absorption in hydrogenated amorphous silicon by photothermal deflection spectroscopy 25(8), 5559-5562. https://doi.org/10.1103/PhysRevB.25.5559
[38] Tabatabaei, K., Sully, H. R., Ju, Z., Hellier, K., Lu, H., Perez, C. J., Newton, K. A., Brutchey, R. L., Bridges, F., Carter, S. A., Kauzlarich, S. M.: Structural Insights on Microwave-Synthesized Antimony-Doped Germanium Nanocrystals 15(1), 1685-1700. https://doi.org/10.1021/acsnano.0c09352
[39] Mehra, R. M., Shyam, R., Mathur, P. C.: Electrical transport in bulk amorphous Se, Se—Te, Se—Sb, and Se—Te—Ge 19(12), 6525-6531. https://doi.org/10.1103/PhysRevB.19.6525
[40] Onsager, L.: Initial Recombination of Ions 54(8), 554-557. https://doi.org/10.1103/PhysRev.54.554
[41] Yip, K., Li, L. S., Chen, I.: On the computation of Onsager quantum efficiency 74(1), 751-753. https://doi.org/10.1063/1.440791
[42] Emelianova, E. V., Arkhipov, V. I., Kasap, S. O., Adriaenssens, G. J.: Charge carrier photogeneration yield in amorphous materials with longrange potential fluctuations 299-302, 305-309. https://doi.org/10.1016/S0022-3093(01)01193-0
[43] Hijazi, N., Kabir, M. Z.: Mechanisms of charge photogeneration in amorphous selenium under high electric fields 27(7), 7534-7539. https://doi.org/10.1007/s10854-016-4733-9
[44] Liraz, D., Tessler, N.: Charge dissociation in organic solar cells—from Onsager and Frenkel to modern models 3(3), 031305. https://doi.org/10.1063/5.0099986
[45] Juška, G., Arlauskas, K.: Impact ionization and mobilities of charge carriers at high electric fields in amorphous selenium 59(1), 389-393. https://doi.org/10.1002/pesa.2210590151
[46] Kasap, S., Koughia, C., Berashevich, J., Johanson, R., Reznik, A.: Charge transport in pure and stabilized amorphous selenium: Re-examination of the density of states distribution in the mobility gap and the role of defects 26(7), 4644-4658. https://doi.org/10.1007/s10854-015-3069-1
[45] HS o on one or atore et the invention can be found in Tuning Amorphous Selenium Composition with Tellurium to Improve Quantum Efficiency at Long Wavelengths and High Applied Fields Kaitlin Hellier, Derek A. Stewart, John Read, Roy Sfadia, and Shiva Abbaszadeh Cite This: ACS Appl. Electron. Mater. 2023, 5, 2678-2685

### Conclusion

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of rights be limited not by this detailed description, but rather by the claims appended hereto.

1. A detector, comprising:
an active region comprising an amorphous alloy comprising selenium and tellurium; and
a biasing circuit comprising a first electrical contact and a second electrical contact to the active region, the biasing circuit for applying an electric field of at least 20 Volts per micrometer between the first contact and the second contact and across the active region.

2. (canceled)

3. The detector of claim 1, wherein the active region comprises less than 12% tellurium and/or consists essentially of amorphous Se₁₋ₓTeₓ with 0.03≤x≤0.12.

4. The detector claim 1, wherein a thickness of the active region between the first contact and the second contact is less than 50 micrometers.

5. The detector of claim 1, wherein the electric field is in a range of 20 volts per micrometer-50 Volts per micrometer and/or in a range wherein quantum efficiency of the detector for detecting electromagnetic radiation having a wavelength corresponding to ultraviolet wavelengths or blue wavelengths is in a range of 80%-100%.

6. The detector claim 1, further comprising a readout circuit comprising the first electrical contact or the second electrical contact, for measuring a photocurrent generated in response to electromagnetic radiation irradiating the active region in a presence of the electric field.

7. A detection system, comprising:
a first direct detector comprising a first amorphous layer comprising selenium that outputs first charge in response to first electromagnetic radiation absorbed in the first amorphous layer and having a first energy, wherein the first charge is used to measure the first incident electromagnetic radiation; and
a second indirect detector under the first direct detector, the second indirect detector comprising a scintillator and a second amorphous layer comprising selenium, wherein:
the scintillator outputs light/electromagnetic radiation in response to second electromagnetic radiation transmitted through the first direct detector and absorbed in the second amorphous layer having a second energy higher than the first energy,
the second amorphous layer outputs second charge in response to the light/electromagnetic radiation outputted from the scintillator, and
the second charge is used to measure the second incident electromagnetic radiation.

8. The detection system of claim 7, wherein at least one of the first amorphous layer or the second amorphous layer comprise an alloy of selenium and tellurium.

9. The system of claim 8, wherein the alloy consists essentially of at least 60% selenium and tellurium as the remainder.

10. The system of claim 7, wherein the first energy is such that at least 50% of the photons of the first electromagnetic radiation comprising X-rays each have an energy below 50 keV and the second energy is such that at least 50% of the photons of the second electromagnetic radiation comprising X-rays have an energy above 50 keV.

11. The system of claim 7, wherein:
the first direct detector comprises:
a first electrical contact;
a second electrical contact;
a first charge blocking layer between the first amorphous layer and the first electrical contact;
a second charge blocking layer between the first amorphous layer and the second electrical contact; and
the second indirect detector comprises:
the scintillator;
a third electrical contact under the scintillator;
a third charge blocking layer between the second amorphous layer and the third electrical contact; and
a fourth charge blocking layer between the second amorphous layer and a fourth electrical contact under the fourth blocking layer; and
wherein each of the blocking layers comprise:
an electron blocking layer or a hole blocking layer; and
at least one of parylene, polyimide, hafnium oxide, aluminum oxide, antimony disulphide (for the electron blocking layer.

12. (canceled)

13. The system of claim 11, further comprising:
a first readout circuit comprising at least one of the first electrical contact or the second electrical contact, for reading out the first charge, and
a second readout circuit comprising at least one of the third electrical contact or the fourth electrical contact, for reading out the second charge.

14. The detection system of claim 13, wherein at least one of the readout circuits is configured as a pixel array or imager for forming one or more images using at least the first charge or the second charge.

15. The detection system of claim 14, wherein the at least one readout circuit comprises transistors arranged in the pixel array to form a thin film transistor flat panel that generates signals from the first charge and/or the second charge so that the signals can be processed to form the one or more images.

16. The detection system of claim 15, wherein the first energy and the second energy are such that the second charge and the first charge can be used to differentiate, in the one or more images, different materials or densities in a sample that interacted with the electromagnetic radiation comprising X-rays prior to detection using the detection system, wherein the different materials are soft and hard tissue or different amounts of calcification.

17. (canceled).

18. A particle physics detection system or industrial quality control system or medical imager for imaging human tissue comprising the detection system of claim 7.

19. (canceled)

20. The detection system of claim 7, wherein the first direct detector is stacked on top of the second indirect detector and each of the first direct detector and the second indirect detector are formed on a base that maintains the first amorphous layer and the second amorphous layer, respectively, in an amorphous state.

21. The detection system of claim 11, wherein:
the first electrical contact and the second electrical contact apply a first bias forming a first electric field across the first amorphous layer, and
the third electrical contact and the fourth electrical contact apply a second bias forming a second electric field across the second amorphous layer, and
the first electric field is at least 10 V/micron, and
the second electric field is at least 20 V/micron.

22. (canceled)

23. The detection system of claim 1, wherein the selenium of the first amorphous layer and/or the second amorphous layer is stabilized selenium comprising 5-20 ppm chlorine and optionally comprises 0.2%-0.5% arsenic.

24. The detection system of claim 7, wherein at least one of the second amorphous layer or the first amorphous layer does not comprise tellurium.

25. The detector of claim 1, wherein:
the tellurium content and electric field are such that:
a sensitivity (or conversion efficiency) of the detector for the electromagnetic radiation having a wavelength below 450 nm is at least as high as for an equivalent detector wherein the only difference is that the active region comprises/consists of non-alloyed amorphous selenium (no tellurium). and
a sensitivity for the wavelengths longer than 450 nm is higher than can be achieved for the equivalent detector comprising the non-alloyed amorphous selenium.
